(19) United States
(12) Patent Application Publication
(10) Pub. No.: US 2007/0054486 A1
(43) Pub. Date: Mar. 8, 2007

(54) METHOD FOR FORMING OPENING

(76) Inventor: Ta-Hung Yang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,277

(22) Filed: Sep. 5, 2005

(51) Int. Cl. H01L 21/4763; H01L 21/302

(52) U.S. Cl. 438/637; 438/736; 438/689; 438/638

(57) ABSTRACT

A method for forming an opening. The method comprises steps of providing a substrate having at least one element structure formed thereon and then forming a dielectric layer over the substrate to cover the element structure. A patterned metal silicide layer is formed on the dielectric layer and then the dielectric layer is etched to form at least one opening by using the patterned metal silicide layer as an etching mask, wherein the opening exposes the corresponding element structure.

### BACKGROUND OF THE INVENTION

1. Field of Invention

The present invention relates to a method for manufacturing a semiconductor device. More particularly, the present invention relates to a method for etching a dielectric layer, a method for forming an opening and a dual damascene process.

2. Description of Related Art

The photolithography process and etching process play important roles in the semiconductor manufacturing process. The purpose for using the photolithography process is to transfer the patterns from the mask onto a photoresist formed on a material layer. Furthermore, the etching process is used to form a patterned material layer by using the patterned photoresist as an etching mask. Since the photoresist is corroded during the etching process is performed, the thickness of the photoresist is increased in order to prevent the pre-reserved portion of the material layer from being etched through during the etching process.

Nevertheless, with respect to those manufacturing process, such as dual damascene process, for forming an opening with a relatively large depth, since the resolution of the photolithography process is decreased with the increase of the thickness of the photoresist, the photoresist cannot provide more effective protection for the material layer. Therefore, the pattern of the photoresist cannot be accurately transferred onto the material layer. Hence, the current method is to use the titanium/titanium nitride layer with a higher resistance as a hard mask layer. However, during the etching process, it is easy for the titanium/titanium nitride hard mask layer to produce particles. Therefore, the quality of the device formed by using the titanium/titanium nitride hard mask layer is affected.

### SUMMARY OF THE INVENTION

Accordingly, at least one objective of the present invention is to provide a method for etching a dielectric layer capable of solving the wafer contamination problem due to the particles generated from the mask layer during the patterning process.

At least a second objective of the present invention is to provide a method for forming an opening with relatively better profile.

The other objective of the present invention is to provide a method for manufacturing a dual damascene opening capable of solving the problem of inaccurately pattern transferring.

To achieve these and other advantages and in accordance with the purpose of the invention, as embodied and broadly described herein, the invention provides a method for etching a dielectric layer, wherein a polysilicon liner layer is located on the dielectric layer and a metal silicide layer is used as an etching mask in an etching process for etching the dielectric layer.

In the present invention, the etching ratio of the dielectric layer to the metal silicide layer is no less than 50. Furthermore, the method for etching the dielectric layer is applied in a metal damascene process or a contact plug process.

The present invention further provides a method for forming an opening. The method comprises steps of providing a substrate having at least one element structure formed thereon and then forming a dielectric layer over the substrate to cover the element structure. Then, a polysilicon liner layer is formed on the dielectric layer. A patterned metal silicide layer is formed over the dielectric layer and then the dielectric layer is etched to form at least one opening by using the patterned metal silicide layer as an etching mask, wherein the opening exposes the corresponding element structure.

In the present invention, the metal silicide layer includes a tungsten silicide layer. In addition, while the metal silicide layer is a tungsten silicide layer, the etching ratio of the dielectric layer to the tungsten silicide layer is no less than 50. Also, the element structure includes a doped region, a gate electrode, a conductive wire or a contact plug and the opening includes a contact opening or a trench. Moreover, after the opening is formed, the aforementioned method further comprises a step of removing the metal silicide layer by using a water/hydrogen peroxide/ammonia solution (standard cleaning solution, SC1) or an ammonia-containing solution. The dielectric layer can be made of silicon oxide. Furthermore, the method for forming the opening can be applied in a metal damascene process or a contact plug process.

The present invention also provides a method for manufacturing a dual metal damascene opening. The method comprises steps of providing a substrate having at least one element structure formed thereon and then forming a dielectric layer over the substrate to cover the element structure. A polysilicon liner layer is formed on the dielectric layer. Further, a metal silicide layer is formed over the dielectric layer and then the metal silicide layer is patterned to expose a first region predetermined to form a contact opening in the dielectric layer. The dielectric layer is etched to form at least one contact opening exposing the corresponding element structure by using the patterned metal silicide layer as an etching mask. The metal silicide layer is patterned to expose a second region predetermined to form a trench in the dielectric layer. The dielectric layer is etched to form at least one trench by using the remaining metal silicide layer as an etching mask, wherein the trench is connected to the contact opening.

In the present invention, the ratio of the dielectric layer to the metal silicide layer is no less than 50. Also, after the trench damascene is formed, the aforementioned method further comprises a step of removing the metal silicide layer by using a water/hydrogen peroxide/ammonia solution (standard cleaning solution, SC1) or an ammonia-containing solution. The dielectric layer can be made of silicon oxide. The metal silicide layer can be made of tungsten silicide.

In the present invention, since the metal silicide layer, such as the tungsten silicide layer, is used as the etching mask layer and the etching selective ratio of the metal silicide layer to the dielectric layer is better, the erosion phenomenon can be effectively suppressed. Therefore, during the process for etching the dielectric layer, the process for forming an opening or the dual damascene process, the pattern can be accurately transferred onto the material layer. In addition, the method according to the present invention can be applied to the process for forming the opening, such as the contact opening in the metal damascene process, with a relatively large depth. Furthermore, the contact opening formed by using the method according to the present invention possesses a better profile.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1E are cross-sectional views illustrating the method for forming a semiconductor device according to one of the preferred embodiment of the present invention.

### DESCRIPTION OF THE PREFERRED EMBODIMENTS

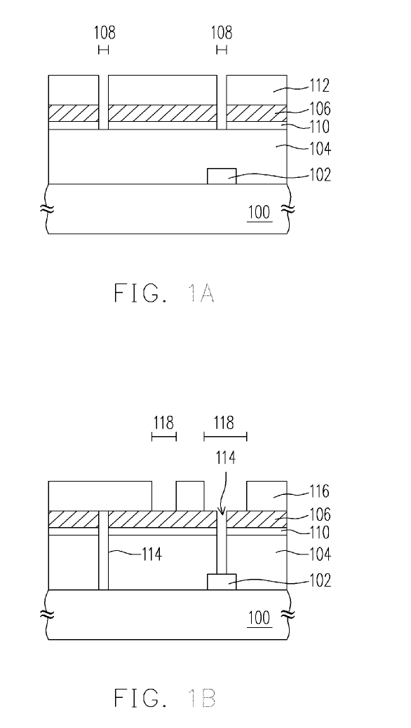

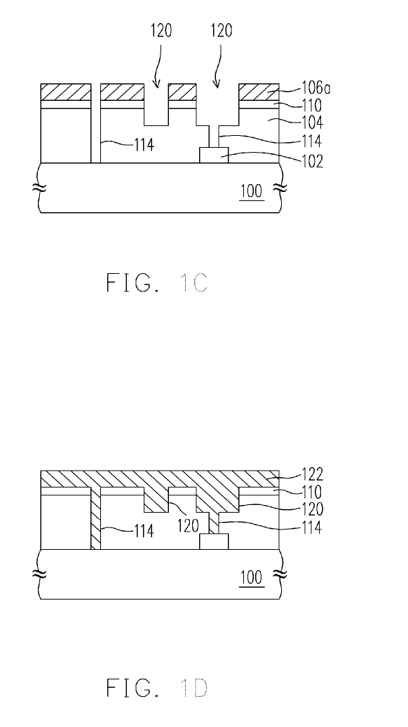

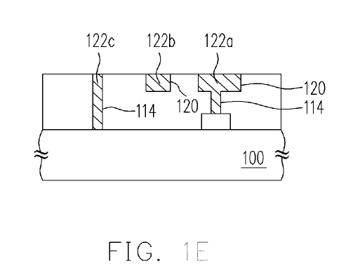

FIGS. 1A through 1E are cross-sectional views illustrating the method for forming a semiconductor device according to one of the preferred embodiment of the present invention.

As shown in FIG. 1A, a substrate 100 is provided, wherein the substrate 100 has at least one element structure 102 formed thereon. The substrate 100 can be, for example but not limited to, a silicon substrate. The element structure 102 can be, for example but not limited to, a gate electrode, a conductive wire or a contact plug and the element structure 102 can be made of cobalt silicide or nickel silicide. Further, in one embodiment, the element structure 102 can be a doped region (not shown) formed in the substrate 100.

Moreover, a dielectric layer 104 is formed over the substrate 100 to cover the element structure 102. The dielectric layer 104 can be, for example but not limited to, made from silicon oxide by performing a chemical vapor deposition.

In addition, a patterned metal silicide layer 106 is formed on the dielectric layer 104. The patterned metal silicide layer 106 exposes a region 108 predetermined to form a contact opening. In one embodiment, the metal silicide layer 106 can be, for example, made of tungsten silicide. Further, the etching selective ratio of the dielectric layer 104 to the metal silicide layer 106 is no less than 50. In addition, in order to increase the adhesion between the patterned metal suicide 106 and the dielectric layer 104, in one embodiment, a liner layer 110 made of polysilicon can be formed between the patterned metal silicide 106 and the dielectric layer 104. Moreover, the method for forming the patterned metal silicide layer 106 and the liner layer 110 includes a patterning process with the use of a photoresist 112.

Furthermore, as shown in FIG. 1B, after the photoresist 112 is removed, the dielectric layer 104 is etched to form at least one contact opening 114 by using the patterned metal silicide layer 106 as the etching mask, wherein the contact opening 114 exposes the corresponding element structure 102. Notably, since the etching selective ratio of the dielectric layer 104 to the metal silicide layer 106 is relatively high, the metal silicide layer 106 can effectively resist the corrosion caused by the etching process during the formation of the contact opening 114. Therefore, the contact opening 114 possesses a relatively better profile. Also, as for the element structure made of cobalt silicide or nickel silicide, since the etching selective ratio of the dielectric material to the metal silicide is relatively high, the element structure is not corroded during the etching process is performed on the dielectric layer 104.

Moreover, a photoresist 116 is formed on the patterned metal silicide layer 106 to expose regions 118 predetermined to form trenches.

As shown in FIG. 1C, the metal silicide layer 106 is patterned by using the photoresist 116 as a mask. After the photoresist 116 is removed, the liner layer 110 and the silicon oxide layer 104 are etched to form at least one trench 120 by using the remaining metal silicide layer 106 as the etching mask, wherein the trench 120 is connected to the contact opening 114. Hence, the trench 120 and the contact opening together form a dual damascene opening. Notably, since the etching selective ratio of the dielectric layer 104 to the metal silicide layer 106a is relatively high, the metal silicide layer 106a can effectively resist the corrosion during the dielectric layer 104 is etched to form the trench 120. Hence, the trench 120 possesses a relatively better profile.

As shown in FIG. 1D, the whole structure is washed by using a water/hydrogen peroxide/ammonia solution (standard cleaning solution, SC1) or an ammonia-containing solution. More specifically, in this washing process, the metal silicide layer 106a is removed.

A conductive layer 122 is formed over the substrate 100 to fill out the trench 120 and the contact opening 114. The conductive layer 122 can be, for example but not limited to, tungsten, copper or other proper conductive material. The method for forming the conductive layer 122 includes a chemical vapor deposition.

As shown in FIG. 1E, a portion of the conductive layer 122 not within the trench 120 and the contact opening 114 is removed to form a dual damascene structure 122a, conductive wire 122b and a contact plug 122c. The method for removing the portion of the conductive layer 122 includes a chemical mechanical (CMP) polishing process. During the CMP process, the liner layer 110 is removed as well. It should be noticed that the metal silicide layer 106a removed in the aforementioned washing process can be also removed together with the liner layer in this CMP process.

Altogether, in the present invention, the method for forming the opening can be applied to the metal damascene process or the process for forming the contact plug. Also, since the etching selective ratio of the dielectric layer to the metal silicide layer is relatively high (no less than 50), the metal silicide layer can be used as the etching mask in the etching process for etching the dielectric layer.

Moreover, because the metal silicide, such as tungsten silicide, is used as the etching mask and the etching selective ratio of the dielectric layer to the metal silicide layer is relatively high, the metal silicide can effectively resist the corrosion. Therefore, during the metal damascene process or the process for forming the opening in the dielectric layer, the pattern can accurately transferred onto the material layer. Further, by using the method according to the present invention, the opening, such as the contact opening formed from dual damascene process, with a relatively large depth can be formed. Also, the contact opening possesses a better profile.

In the present invention, although, in the preferred embodiment, the present invention is detailed described by using the process for forming the dual damascene opening including the steps of forming the contact opening and then forming the trench, the present invention can be presented by another dual damascene opening process comprising the steps of forming the trench and then forming the contact opening.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for etching a dielectric layer, wherein a polysilicon liner layer is located on the dielectric layer and a metal silicide layer is used as an etching mask in an etching process for etching the dielectric layer.

2. The method of claim 1, wherein the etching selective ratio of the dielectric layer to the metal silicide layer is no less than 50.

3. The method of claim 1, wherein the method for etching the dielectric layer is applied in a metal damascene process or a contact plug process.

4. A method for forming an opening, comprising:
providing a substrate having at least one element structure formed thereon;
forming a dielectric layer over the substrate to cover the element structure;
forming a polysilicon liner layer on the dielectric layer;
forming a patterned metal silicide layer over the dielectric layer; and
etching the dielectric layer to form at least one opening by using the patterned metal silicide layer as an etching mask, wherein the opening exposes the corresponding element structure.

5. The method of claim 4, wherein the metal silicide layer includes a tungsten silicide layer.

6. The method of claim 5, wherein the etching selective ratio of the dielectric layer to the tungsten silicide layer is no less than 50.

7. The method of claim 4, wherein the element structure includes a doped region, a gate electrode, a conductive wire or a contact plug.

8. The method of claim 4, wherein the opening includes a contact opening or a trench.

9. The method of claim 4, after the opening is formed, further comprising a step of removing the metal silicide layer by using a water/hydrogen peroxide/ammonia solution (standard cleaning solution, SC1).

10. The method of claim 4, after the opening is formed, further comprising a step of removing the metal silicide layer by using an ammonia-containing solution.

11. The method of claim 4, wherein the dielectric layer is made of silicon oxide.

12. The method of claim 4, wherein the method for forming the opening is applied in a metal damascene process or a contact plug process.

13. A method for manufacturing a dual metal damascene opening, comprising:
providing a substrate having at least one element structure formed thereon;
forming a dielectric layer over the substrate to cover the element structure;
forming a polysilicon liner layer on the dielectric layer;
forming a metal silicide layer over the dielectric layer;
patterning the metal silicide layer to expose a first region predetermined to form a contact opening in the dielectric layer;
etching the dielectric layer to form at least one contact opening exposing the corresponding element structure by using the patterned metal silicide layer as an etching mask;
patterning the metal silicide layer to expose a second region predetermined to form a trench in the dielectric layer; and
etching the dielectric layer to form at least one trench damascene by using the remaining metal silicide layer as an etching mask, wherein the trench is connected to the contact opening.

14. The method of claim 13, wherein the etching selective ratio of the dielectric layer to the metal silicide layer is no less than 50.

15. The method of claim 13, after the trench damascene is formed, further comprising a step of removing the metal silicide layer by using a water/hydrogen peroxide/ammonia solution (standard cleaning solution, SC1).

16. The method of claim 13, after the trench damascene is formed, further comprising a step of removing the metal silicide layer by using an ammonia-containing solution.

17. The method of claim 13, wherein the dielectric layer is made of silicon oxide.

18. The method of claim 13, further comprising a step of forming trench opening first and contact opening last.

19. The method of claim 13, further comprising a step of forming trench opening only (single damascene).

20. The method of claim 13, wherein the metal silicide is made of tungsten silicide.
